(19) United States
(12) Patent Application Publication
(10) Pub. No.: US 2026/0293527 A1
(43) Pub. Date: Sep. 24, 2026

(54) PIEZOELECTRIC ELEMENT, LIQUID EJECTING HEAD, AND LIQUID EJECTING APPARATUS

(71) Applicant: SEIKO EPSON CORPORATION, Tokyo (JP)

(72) Inventors: Koji OHASHI, MATSUMOTO-SHI (JP); Nobuaki ITO, SUWA-SHI (JP); Yasuaki HAMADA, CHINO-SHI (JP); Masao NAKAYAMA, MATSUMOTO-SHI (JP)

(21) Appl. No.: 19/574,519

(22) Filed: Mar. 23, 2026

(30) Foreign Application Priority Data
Mar. 24, 2025 (JP) 2025-048896

(51) Int. Cl. H10N 30/85; B41J 2/16; H10N 30/00

(52) U.S. Cl. CPC H10N 30/852; B41J 2/161; H10N 30/704

(57) ABSTRACT

A piezoelectric element includes: a lower electrode; a lower piezoelectric body including K, Na, and Nb; an upper piezoelectric body including K, Na, and Nb; and an upper electrode, in which the lower electrode, the lower piezoelectric body, the upper piezoelectric body, and the upper electrode are provided to be arranged in this order in a lamination direction, and when an average concentration of K in the lower piezoelectric body is represented by K1, an average concentration of Na in the lower piezoelectric body is represented by Na1, an average concentration of K in the upper piezoelectric body is represented by K2, and an average concentration of Na in the upper piezoelectric body is represented by Na2, K1/(K1+Na1)>K2/(K2+Na2) is satisfied.

The present application is based on, and claims priority from JP Application Serial Number 2025-048896, filed Mar. 24, 2025, the disclosure of which is hereby incorporated by reference herein in its entirety.

### BACKGROUND

### 1. Technical Field

The present disclosure relates to a piezoelectric element, a liquid ejecting head, and a liquid ejecting apparatus.

### 2. Related Art

Image forming devices including liquid ejecting heads that eject liquids such as inks onto a medium such as printing paper were proposed in the related art. As the liquid ejecting head, a head that ejects a liquid filled in a pressure chamber from a nozzle by vibrating a diaphragm forming a wall surface of the pressure chamber with a piezoelectric element is known.

A piezoelectric element described in JP-A-2011-155272 includes a piezoelectric body formed of (KₐNa₁₋ₐ)NbO₃ including K, Na, and Nb. (KₐNa₁₋ₐ)NbO₃ has a perovskite structure represented by Formula ABO₃ and is abbreviated as KNN.

Displacement characteristics of the KNN piezoelectric body are lower than displacement characteristics of, for example, lead zirconate titanate (PZT). Therefore, in order to improve the displacement characteristics of the piezoelectric element, a plurality of layers need to be laminated to improve the displacement characteristics of the KNN piezoelectric body. For example, a case where the KNN piezoelectric body is formed of a laminate including an upper layer and a lower layer can be considered. In this case, the present inventors found that a more preferable effect can be obtained by setting a composition for each of the upper layer and the lower layer rather than setting the same composition for the upper layer and the lower layer.

### SUMMARY

A piezoelectric element according to a preferred aspect of the present disclosure includes: a lower electrode; a lower piezoelectric body including K, Na, and Nb; an upper piezoelectric body including K, Na, and Nb; and an upper electrode, in which the lower electrode, the lower piezoelectric body, the upper piezoelectric body, and the upper electrode are provided to be arranged in this order in a lamination direction, and when an average concentration of K in the lower piezoelectric body is represented by K1, an average concentration of Na in the lower piezoelectric body is represented by Na1, an average concentration of K in the upper piezoelectric body is represented by K2, and an average concentration of Na in the upper piezoelectric body is represented by Na2, K1/(K1+Na1)>K2/(K2+Na2) is satisfied.

A liquid ejecting head according to a preferred aspect of the present disclosure includes: a piezoelectric element; a pressure chamber in which liquid is circulated to apply a pressure to the liquid by the piezoelectric element; and a nozzle configured to eject the liquid using the pressure applied in the pressure chamber.

A liquid ejecting apparatus according to a preferred aspect of the present disclosure includes: the liquid ejecting head; and a controller configured to control an ejecting operation from the liquid ejecting head.

### BRIEF DESCRIPTION OF THE DRAWINGS

FIG. 1 is a schematic view illustrating a configuration of a liquid ejecting apparatus according to a first embodiment.

FIG. 2 is an exploded perspective view of a liquid ejecting head illustrated in FIG. 1.

FIG. 3 is a cross-sectional view of a part of the liquid ejecting head illustrated in FIG. 2.

FIG. 4 is a diagram illustrating a diaphragm and a piezoelectric element of FIG. 3.

FIG. 5 is a diagram illustrating a hysteresis curve.

FIG. 6 is a diagram illustrating a relationship between a field intensity and a capacitance regarding a third example and a fourth example of FIG. 5.

FIG. 7 is a table illustrating a relationship between a K content and a positive saturated polarization.

FIG. 8 is a graph illustrating the relationship between the K content and the positive saturated polarization.

FIG. 9 is a table illustrating Examples.

FIG. 10 is a table illustrating Comparative Examples.

### DESCRIPTION OF EMBODIMENTS

Hereinafter, preferred embodiments according to the present disclosure will be described with reference to the accompanying drawings. In the drawings, dimensions or scales of each section are different from the actual dimensions or scales as appropriate, and some sections are schematically illustrated for easy understanding. Further, the scope of the present disclosure is not limited to these embodiments unless it is noted in the following description that the present disclosure is particularly limited. In addition, the phrase “the element α and the element β are laminated” means that the element α and the element β need only be arranged in an up-down direction, and whether the element α and the element β are in direct contact with each other is not a problem.

The following description will be made by using an X-axis, a Y-axis, and a Z-axis that intersect each other, as appropriate. One direction along the X-axis will be referred to as an X1 direction, and a direction opposite to the X1 direction will be referred to as an X2 direction. Directions opposite to each other along the Y-axis will be referred to as a Y1 direction and a Y2 direction. Directions opposite to each other along the Z-axis will be referred to as a Z1 direction and a Z2 direction. Viewing in a direction along the Z-axis will be referred to as a “plan view”. The Z-axis is typically a vertical axis. The Z1 direction is an upper side, and the Z2 direction is a lower side. Meanwhile, the Z-axis does not need to be the vertical axis. The X-axis, the Y-axis, and the Z-axis are typically orthogonal to each other, but are not limited thereto, and may intersect each other at, for example, an angle within a range of, for example, 80° or more and 100° or less.

### 1. First Embodiment

### 1-1. Overall Configuration of Liquid Ejecting Apparatus 100

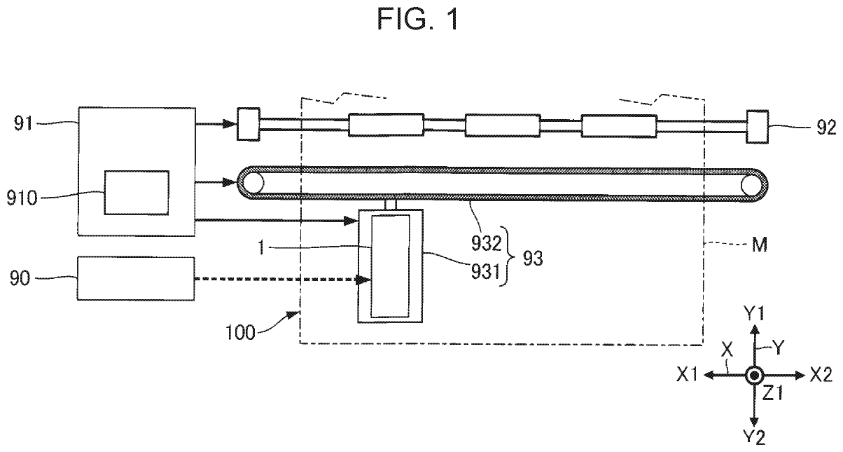

FIG. 1 is a configuration view schematically illustrating a liquid ejecting apparatus 100 according to a first embodiment. The liquid ejecting apparatus 100 is an ink jet printing apparatus that ejects ink, which is an example of liquid, to a medium M as liquid droplets. The medium M is typically printing paper. The medium M is not limited to the printing paper, and may be, for example, a printing target having any material such as a resin film or fabric.

As illustrated in FIG. 1, the liquid ejecting apparatus 100 is equipped with a liquid container 90 for storing the ink. Examples of specific aspects of the liquid container 90 include a cartridge that can be attached to and detached from the liquid ejecting apparatus 100, a bag-shaped ink pack formed of a flexible film, and an ink tank that can be refilled with the ink. A type of the ink stored in the liquid container 90 is optional. In addition, “liquid” may be any material that can be ejected from the liquid ejecting apparatus 100. For example, “liquid” may be a material where liquid includes solid matter.

The liquid ejecting apparatus 100 includes a controller 91, a transport mechanism 92, a moving mechanism 93, and a liquid ejecting head 1. The controller 91 includes, for example, a processing circuit such as a central processing unit (CPU) or a field programmable gate array (FPGA) and a storage circuit such as a semiconductor memory, and controls the operation of each element of the liquid ejecting apparatus 100. The controller 91 includes a voltage application circuit 910 that causes a nozzle to eject the ink by controlling driving of a piezoelectric element 5 described below. The voltage application circuit 910 applies a reference voltage VBS and a driving voltage Com to the piezoelectric element 5 described below provided in the liquid ejecting head 1.

The transport mechanism 92 transports the medium M in the Y2 direction under the control of the controller 91. The moving mechanism 93 causes the liquid ejecting head 1 to reciprocate in the X1 direction and the X2 direction under the control of the controller 91. In the example illustrated in FIG. 1, the moving mechanism 93 includes a substantially box-shaped transport body 931 called a carriage that accommodates the liquid ejecting head 1, and a transport belt 932 to which the transport body 931 is fixed. The number of liquid ejecting heads 1 mounted on the transport body 931 is not limited to one, and may be plural. The liquid container 90 may be mounted on the transport body 931 in addition to the liquid ejecting head 1.

Under the control of the controller 91, the liquid ejecting head 1 ejects the ink supplied from the liquid container 90 to the medium M from each of a plurality of nozzles toward the Z2 direction. Although described below, the liquid ejecting head 1 includes a plurality of piezoelectric elements 5 for ejecting ink from a plurality of nozzles N. By performing the ejection in parallel with the transport of the medium M via the transport mechanism 92 and the reciprocating movement of the liquid ejecting head 1 via the moving mechanism 93, an image is formed at a surface of the medium M using the ink.

As described above, the liquid ejecting apparatus 100 includes the liquid ejecting head 1, and the controller 91 that controls the ejecting operation from the liquid ejecting head 1. The liquid ejecting head 1 has characteristics described below, that is, an effect that the occurrence of cracking of the piezoelectric element 5 caused by sudden occurrence of an overcurrent can be suppressed, and the occurrence of a driving delay can be suppressed. Therefore, according to the liquid ejecting apparatus 100 including the liquid ejecting head 1, a decrease in ejecting performance can be suppressed.

### 1-2. Overall Configuration of Liquid Ejecting Head 1

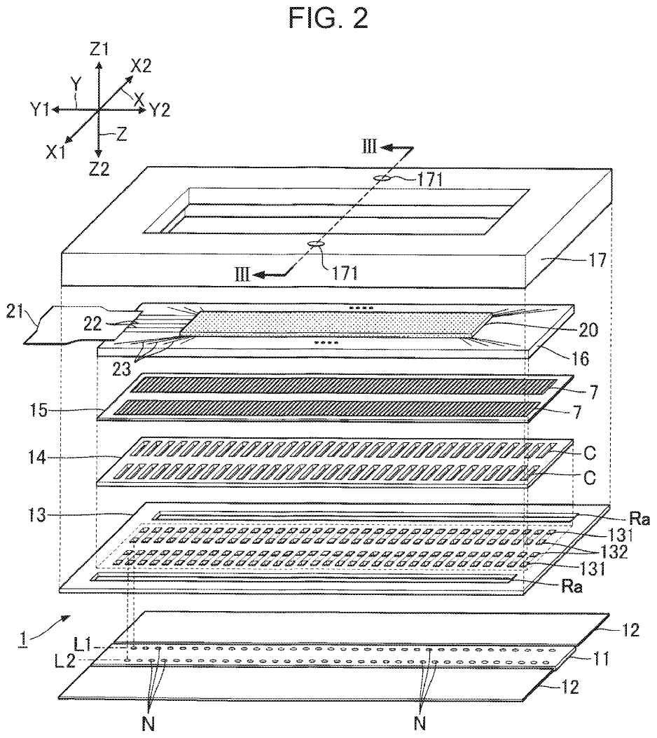

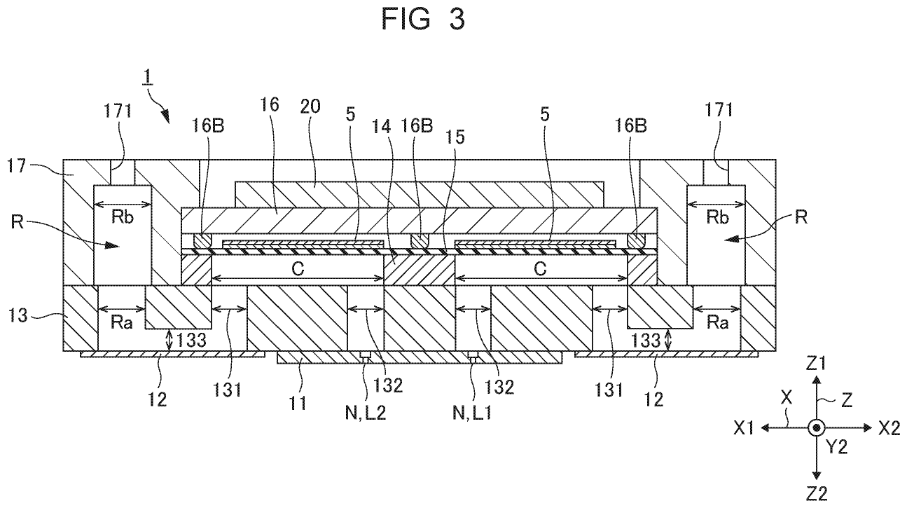

FIG. 2 is an exploded perspective view of the liquid ejecting head 1 illustrated in FIG. 1. FIG. 3 is a cross-sectional view of a part of the liquid ejecting head 1 illustrated in FIG. 2, and is a cross-sectional view taken along line III-III in FIG. 2.

As illustrated in FIG. 2, the liquid ejecting head 1 includes a plurality of nozzles N arranged in the direction along the Y-axis. In the example illustrated in FIG. 2, the plurality of nozzles N are divided into a first row L1 and a second row L2 arranged at intervals in the direction along the X-axis. Each of the first row L1 and the second row L2 is a set of the plurality of nozzles N linearly arranged in the direction along the Y-axis. An element related to each nozzle N in the first row L1 and an element related to each nozzle N in the second row L2 in the liquid ejecting head 1 are substantially symmetrical to each other in the direction along the X-axis. In the following description, the element corresponding to the first row L1 will be mainly described, and the description of the element corresponding to the second row L2 will be omitted as appropriate.

The positions of the plurality of nozzles N in the first row L1 and the positions of the plurality of nozzles N in the second row L2 in the direction along the Y-axis may be the same as or may be different from each other. In addition, the element related to each nozzle N in one of the first row L1 and the second row L2 may be omitted.

As illustrated in FIGS. 2 and 3, the liquid ejecting head 1 includes a nozzle plate 11, a vibration absorber 12, a flow path substrate 13, a pressure chamber substrate 14, a diaphragm 15, a wiring substrate 16, a housing portion 17, and a driving circuit 20. Each of the nozzle plate 11, the vibration absorber 12, the flow path substrate 13, the pressure chamber substrate 14, the diaphragm 15, the wiring substrate 16, and the housing portion 17 is a plate-shaped member that is elongated in the direction along the Y-axis. The nozzle plate 11, the flow path substrate 13, the pressure chamber substrate 14, the diaphragm 15, and the wiring substrate 16 are arranged in this order in the Z1 direction.

The nozzle plate 11 is a plate-shaped member in which the plurality of nozzles N are formed. Each of the plurality of nozzles N is a circular through-hole through which the ink passes. The nozzle N ejects the ink by the vibration of the diaphragm 15. The nozzle plate 11 is bonded to the flow path substrate 13 using, for example, an adhesive. The nozzle N is a portion that ejects the liquid using a pressure applied in a pressure chamber C.

The flow path substrate 13 is formed with a flow path for supplying the ink to the plurality of nozzles N. Specifically, in the flow path substrate 13, a space Ra, a plurality of supply flow paths 131, a plurality of communication flow paths 132, and a supply liquid chamber 133 are formed. The space Ra is an elongated opening extending in the direction along the Y-axis in a plan view when viewed in the direction along the Z-axis. Each of the supply flow paths 131 and the communication flow paths 132 is a through-hole formed for each nozzle N. The supply liquid chamber 133 is an elongated space extending in the direction along the Y-axis over the plurality of nozzles N, and allows the space Ra and the plurality of supply flow paths 131 to communicate with each other. Each of the plurality of communication flow paths 132 overlaps one nozzle N corresponding to the communication flow path 132 in a plan view. The pressure chamber substrate 14 is bonded to the flow path substrate 13 using, for example, an adhesive.

In the pressure chamber substrate 14, a plurality of pressure chambers C are provided. The plurality of pressure chambers C are arranged in the direction along the Y-axis. Each pressure chamber C is formed for each nozzle N, and is an elongated space extending in the direction along the X-axis in a plan view. The pressure chamber C is a space located between the flow path substrate 13 and the diaphragm 15. The pressure chamber C communicates with the nozzle N via the communication flow path 132 and communicates with the space Ra via the supply flow path 131 and the supply liquid chamber 133. The pressure chamber C is a portion in which ink that is liquid is circulated to apply a pressure to the ink by the piezoelectric element 5.

Each of the nozzle plate 11, the flow path substrate 13, and the pressure chamber substrate 14 is manufactured by processing a silicon single crystal substrate using, for example, dry etching or wet etching. However, other known methods may be used as appropriate for manufacturing the nozzle plate 11, the flow path substrate 13, and the pressure chamber substrate 14.

The diaphragm 15 is disposed on a surface of the pressure chamber substrate 14 facing the Z1 direction. The diaphragm 15 is a plate-shaped member that can elastically vibrate.

A plurality of piezoelectric elements 5 corresponding to the nozzles N are disposed on a surface of the diaphragm 15 facing the Z1 direction. Each piezoelectric element 5 has an elongated shape extending in the direction along the X-axis in a plan view. The plurality of piezoelectric elements 5 correspond to the plurality of pressure chambers C, and are arranged in the direction along the Y-axis. The piezoelectric element 5 is deformed due to the application of a voltage. When the diaphragm 15 vibrates in conjunction with the deformation, the pressure in the pressure chamber C fluctuates, so that the ink is ejected from the nozzle N.

The housing portion 17 is a case for storing the ink supplied to the plurality of pressure chambers C. As illustrated in FIG. 3, a space Rb is formed in the housing portion 17. The space Rb of the housing portion 17 and the space Ra of the flow path substrate 13 communicate with each other. A space formed by the space Ra and the space Rb functions as a liquid storage chamber R that is a reservoir that stores the ink supplied to the plurality of pressure chambers C. The ink is supplied to the liquid storage chamber R through an inlet 171 formed in the housing portion 17. The ink in the liquid storage chamber R is supplied to the pressure chamber C through the supply liquid chamber 133 and each supply flow path 131.

The vibration absorber 12 is a flexible film that forms a wall surface of the liquid storage chamber R. The vibration absorber 12 is a compliance substrate that absorbs the fluctuation in the pressure of the ink in the liquid storage chamber R.

The wiring substrate 16 is a plate-shaped member in which wirings for electrically coupling the driving circuit 20 and the plurality of piezoelectric elements 5 are formed. A surface of the wiring substrate 16 facing the Z2 direction is bonded to the diaphragm 15 via a plurality of conductive bumps 16B. On the other hand, the driving circuit 20 is mounted on a surface of the wiring substrate 16 facing the Z1 direction. The driving circuit 20 is an integrated circuit (IC) chip that outputs the driving voltage Com and the reference voltage VBS for driving each piezoelectric element 5.

As illustrated in FIG. 2, an end portion of an external wiring 21 is bonded to a surface of the wiring substrate 16 facing the Z1 direction. The external wiring 21 is formed of, for example, coupling components such as flexible printed circuits (FPC) or flexible flat cables (FFC). The wiring substrate 16 is formed with a plurality of wirings 22 that electrically couple the external wiring 21 and the driving circuit 20, and a plurality of wirings 23 to which the driving voltage Com and the reference voltage VBS output from the driving circuit 20 are supplied.

The wiring substrate 16 is not limited to a rigid substrate, and may be, for example, flexible printed circuits (FPC) or a flexible flat cable (FFC). In this case, the wiring substrate 16 may also serve as the external wiring 21.

In this liquid ejecting head 1, when the piezoelectric elements 5 are bent and deformed due to the application of a voltage, the diaphragm 15 is bent and deformed, that is, vibrates, in a direction in which the volume of the pressure chambers C decreases. As a result, the pressure in the pressure chambers C changes, and the ink in the pressure chambers C is ejected from the nozzle N. The piezoelectric element 5 returns to the original position after the ink is ejected.

As described above, the liquid ejecting head 1 includes the piezoelectric element 5, the pressure chamber C in which ink that is liquid is circulated to apply a pressure to the ink by the piezoelectric element 5, and the nozzle N that eject the ink using a pressure applied in the pressure chamber C. The liquid ejecting head 1 includes the piezoelectric element 5 having the characteristics described below. Therefore, the occurrence of cracking of the piezoelectric layer 53 caused by sudden occurrence of an overcurrent can be suppressed, and the occurrence of a driving delay can be suppressed.

In addition, the liquid ejecting head 1 includes all of each of the elements illustrated in FIG. 3. However, the components of the liquid ejecting head 1 do not need to include all of the elements and may further include additional elements.

### 1-3. Diaphragm 15 and Piezoelectric Element 5

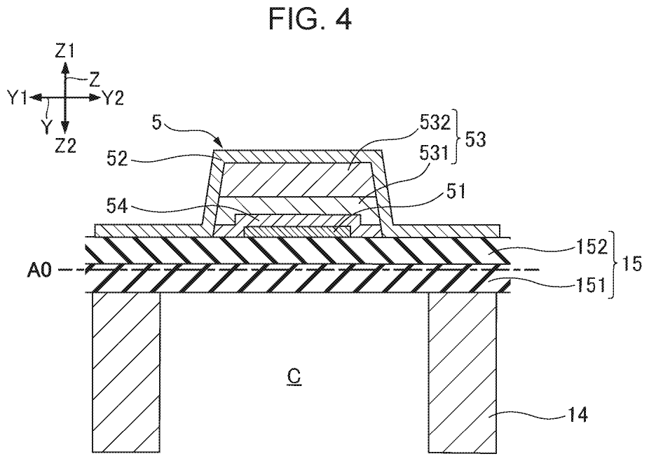

FIG. 4 is a cross-sectional view illustrating the diaphragm 15 and the piezoelectric element 5 of FIG. 3. In the example illustrated in FIG. 4, the diaphragm 15 is formed of a laminate including a first vibration layer 151 and a second vibration layer 152. The first vibration layer 151 is in contact with the pressure chamber substrate 14. The second vibration layer 152 is disposed above the first vibration layer 151. The first vibration layer 151 is formed of an elastic material such as silicon oxide (SiOₓ). The second vibration layer 152 is formed of an insulating material such as zirconium oxide (ZrOₓ). The first vibration layer 151 is formed, for example, by thermally oxidizing a part of the pressure chamber substrate 14. The second vibration layer 152 is formed, for example, by a known film forming technique such as sputtering. The diaphragm 15 may be formed of a single layer or may be formed of three or more layers. FIG. 4 illustrates a neutral axis A1 of the diaphragm 15.

The piezoelectric element 5 is provided on the diaphragm 15. The piezoelectric element 5 mainly includes a lower electrode 51, a piezoelectric layer 53, an upper electrode 52, and a seed layer 54. The piezoelectric layer 53 includes a lower piezoelectric body 531 and an upper piezoelectric body 532. The lower electrode 51, the seed layer 54, the lower piezoelectric body 531, the upper piezoelectric body 532, and the upper electrode 52 are provided to be arranged along the Z2 direction that is a lamination direction.

The lower electrode 51 is provided above the diaphragm 15. The lower electrode 51 is an individual electrode provided for each piezoelectric element 5. The driving voltage Com that fluctuates is applied to the lower electrode 51. The lower electrode 51 is elongated along the X-axis. A plurality of lower electrodes 51 are arranged along the Y-axis at intervals. The lower electrode 51 includes, for example, a conductive material such as platinum (Pt). The thickness of the lower electrode 51 along the Z-axis is not particularly limited, and is, for example, 50 nm or more and 120 nm or less. In addition, the lower electrode 51 may be formed of a single layer or may be formed of a plurality of layers.

The seed layer 54 is provided for controlling an orientation of the piezoelectric layer 53. The thickness of the seed layer 54 along the Z-axis is less than the thickness of the piezoelectric layer 53 along the Z-axis. The thickness of the seed layer 54 along the Z-axis is not particularly limited, and is, for example, 5 nm or more and 50 nm or less. In addition, the seed layer 54 may be formed of a single layer or may be formed of a plurality of layers.

For example, the seed layer 54 has a Perovskite structure. The seed layer 54 includes, for example, lead titanate PbₐTi_{b}O_{z}, lanthanum nickel oxide LaₐNi_{b}O_{z}, PbₓBi₍ₐ₋ₓ₎Fe_{y}Ti_{(b-y)}O_{z}, BiₐFe_{y}Ti_{(b-y)}O_{z}, or PbₐFe_{y}Ti_{(b-y)}O_{z}. In the above-described chemical formulae, it is necessary to satisfy 0<x<a and 0<y<b. In addition, the seed layer 54 may include a composite oxide having a perovskite structure including Bi, Fe, and Ti. In particular, it is preferable that the seed layer 54 includes PbₓBi₍ₐ₋ₓ₎Fe_{y}Ti_{(b-y}O_{z}. PbₓBi₍ₐ₋ₓ₎Fe_{y}Ti_{(b-y)}O_{z} is more preferable due to its excellent orientation controllability.

The piezoelectric layer 53 is, for example, a strip-shaped dielectric film that is continuous along the Y-axis across the plurality of piezoelectric elements 5. The piezoelectric layer 53 has, for example, a strip shape extending along the Y-axis and is separated for each piezoelectric element 5 by forming a plurality of notches. The thickness of the piezoelectric layer 53 along the Z-axis is not particularly limited, and is, for example, 300 nm or more and 1500 nm or less.

The upper electrode 52 is provided above the piezoelectric layer 53. The upper electrode 52 is a strip-shaped common electrode that extends along the Y-axis so as to be continuous across the plurality of the piezoelectric elements 5. The predetermined reference voltage VBS is applied to the upper electrode 52. The upper electrode 52 includes, for example, a conductive material such as iridium (Ir). The thickness of the upper electrode 52 along the Z-axis is not particularly limited, and is, for example, 50 nm or more and 120 nm or less. In addition, the upper electrode 52 may be formed of a single layer or may be formed of a plurality of layers.

In the piezoelectric element 5, a voltage corresponding to a difference between the reference voltage VBS applied to the upper electrode 52 and the driving voltage Com corresponding to the ejection amount supplied to the lower electrode 51 is applied to the piezoelectric layer 53. By applying a voltage between the lower electrode 51 and the upper electrode 52, the piezoelectric layer 53 deforms such that the piezoelectric element 5 is bent and deformed, that is, vibrates.

In the present embodiment, the lower electrode 51 is an individual electrode and the upper electrode 52 is a common electrode. However, the lower electrode 51 may be a common electrode, and the upper electrode 52 may be an individual electrode.

### 1-4. Piezoelectric Layer 53

The piezoelectric layer 53 is formed of, for example, a laminated including a plurality of layers. Specifically, as described above, the piezoelectric layer 53 is formed of the lower piezoelectric body 531 and the upper piezoelectric body 532.

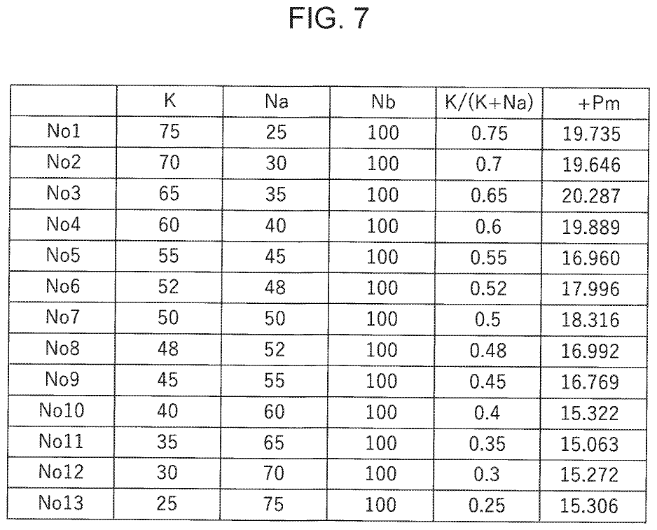

The lower piezoelectric body 531 may be formed of a single layer or may be formed of a plurality of layers. Likewise, the upper piezoelectric body 532 may be formed of a single layer or may be formed of a plurality of layers. Here, as illustrated in FIG. 7 below, the lower piezoelectric body 531 is formed of a single material, and the upper piezoelectric body 532 is also formed of a single material.

In addition, the lower piezoelectric body 531 includes K, Na, and Nb. Likewise, the upper piezoelectric body 532 includes K, Na, and Nb. Specifically, each of the lower piezoelectric body 531 and the upper piezoelectric body 532 has a perovskite structure that includes K and Na in an A-site and includes Nb in a B-site. Specifically, each of the lower piezoelectric body 531 and the upper piezoelectric body 532 includes potassium sodium niobate ((KₐNa₁₋ₐ)NbO₃). (KₐNa₁₋ₐ)NbO₃ has a perovskite structure represented by Formula ABO₃ and is abbreviated as KNN.

Each of the lower piezoelectric body 531 and the upper piezoelectric body 532 is manufactured, for example, using a MOD method, a sol-gel method, or a sputtering method. For example, the upper piezoelectric body 532 is manufactured with a sputtering method using a metal complex including K, Na, and Nb, and the lower piezoelectric body 531 is manufactured using a sol-gel method. The sol-gel method is a method of applying a precursor solution formed of a sol to the lower layer to form a piezoelectric precursor film, and drying and degreasing the piezoelectric precursor film at a predetermined temperature. In addition, the MOD method is a method of applying a MOD solution to the lower layer and drying and degreasing the MOD solution. When the piezoelectric layer 53 is formed by a sol-gel process, a precursor solution containing K, Na, and Nb compounds is applied onto a substrate, followed by drying and calcination at a predetermined temperature to obtain a perovskite structure. In this case, the ratios of K, Na and Nb are controlled during solution preparation prior to coating and firing, and correspond to the intended composition of the resulting layer. Minor deviations after thermal treatment are acceptable within typical process tolerances.

As described above, the piezoelectric layer 53 is formed of the lower piezoelectric body 531 and the upper piezoelectric body 532. Therefore, displacement characteristics of the piezoelectric layer 53 can be improved as compared to when the piezoelectric layer 53 is formed of one piezoelectric body.

In addition, in the piezoelectric layer 53, when the piezoelectric layer 53 expands and contracts for ejecting the liquid, a phenomenon in which a neutral axis A1 is shifted to the upper side. Along with the shift of the neutral axis A1, In both of the lower piezoelectric body 531 and the upper piezoelectric body 532, a phenomenon in which the displacement decreases to be less than an ideal value in a high voltage range occurs. In the lower piezoelectric body 531 having a small distance from the neutral axis A1, this displacement decrease in the high voltage range significantly occurs.

Incidentally, when an unexpected overcurrent suddenly occurs in the piezoelectric layer 53, the displacement upper limit of the piezoelectric layer 53 is exceeded, and cracking may occur. For this phenomenon, the above-described displacement decrease in the high voltage range is effective. The reason for this is that, due to the shift of the neutral axis A1, displacement characteristics do not change until a medium voltage range, and the displacement decrease is selectively caused to occur in the high voltage range. In order to effectively obtain this effect, it is preferable to increase a piezoelectric constant of the lower piezoelectric body 531. To that end, it is preferable to increase a saturated polarization Pm of the lower piezoelectric body 531.

The contribution of the upper piezoelectric body 532 to the above-described effect of suppressing the overcurrent is smaller than the lower piezoelectric body 531. However, the above-described effect of suppressing the overcurrent can be obtained by the upper piezoelectric body 532. From the viewpoint, it can also be considered to increase the saturated polarization Pm of the lower piezoelectric body 531 as in the saturated polarization Pm of the upper piezoelectric body 532. However, the lower piezoelectric body 531 and the upper piezoelectric body 532 are coupled in series. Therefore, when both of the saturated polarizations Pm of the lower piezoelectric body 531 and the upper piezoelectric body 532 are increased, the capacitance may increase locally. As a result, high-frequency driving is interrupted, and a delay may occur in the driving.

From the above, in order to suppress the overcurrent and to reduce the occurrence of the driving delay in the high-frequency driving simultaneously, the amount of the saturated polarization needs to be controlled in each of the lower piezoelectric body 531 and the upper piezoelectric body 532. As a result of a thorough investigation by the present inventors, it was found that the amount of the saturated polarization can be controlled by setting a K/Na ratio for each of the lower piezoelectric body 531 and the upper piezoelectric body 532.

Specifically, an average concentration of potassium (K) in the lower piezoelectric body 531 is represented by K1 [mol %], an average concentration of sodium (Na) in the lower piezoelectric body 531 is represented by Na1 [mol %], an average concentration of K in the upper piezoelectric body 532 is represented by K2 [mol %], and an average concentration of Na in the upper piezoelectric body 532 is represented by Na2 [mol %]. In this case, the average concentrations K1, K2, Na1, and Na2 satisfy the following relationship.

$$K 1 / ( K 1 + Na 1 ) > K 2 / ( K 2 + Na 2 )$$

That is, a K content in the A-site of the lower piezoelectric body 531 is higher than a K content in the A-site of the upper piezoelectric body 532.

The average concentrations K1, K2, Na1, and Na2 satisfy the above-described relationship such that the saturated polarization Pm of the lower piezoelectric body 531 can be set to be higher than the saturated polarization Pm of the upper piezoelectric body 532. Therefore, by increasing the saturated polarization Pm of the lower piezoelectric body 531, the piezoelectric constant of the lower piezoelectric body 531 can be increased. Accordingly, the displacement of the piezoelectric layer 53 in the high voltage range can be decreased, and thus a concern of cracking caused by sudden application of an unexpected overcurrent to the piezoelectric layer 53 can be suppressed. Further, the saturated polarization Pm of the lower piezoelectric body 531 can be increased to be higher than the saturated polarization Pm of the upper piezoelectric body 532. Therefore, a local increase in capacitance caused by increasing both of the saturated polarizations Pm of the lower piezoelectric body 531 and the upper piezoelectric body 532 to be the same can be suppressed. From the above, a concern of cracking caused by sudden application of an overcurrent can be suppressed, and the occurrence of the driving delay in the high-frequency driving can be reduced.

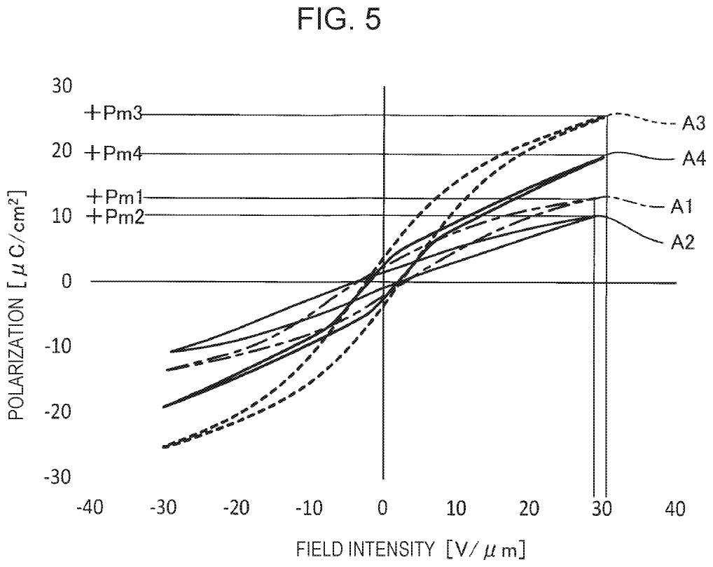

FIG. 5 is a diagram illustrating a hysteresis curve. FIG. 5 illustrates four types of hysteresis curves of a first example A1, a second example A2, a third example A3, and a fourth example A4. In FIG. 5, the horizontal axis represents a field intensity [V/μm], and the vertical axis represents a polarization [μC/cm²]. In each of the hysteresis curves, a portion having the maximum field intensity corresponds to a positive saturated polarization +Pm. In FIG. 5 the positive saturated polarizations +Pm of the first example A1, the second example A2, the third example A3, and the fourth example A4 are illustrated as positive saturated polarizations +Pm1, +Pm2, +Pm3, and +Pm4.

Each of the first example A1 and the second example A2 is a piezoelectric body including a single layer that is formed of KNN. Specifically, in the piezoelectric body including a single layer of the first example A1, K is 65 [mol %], and Na is 35 [mol %]. That is, the piezoelectric body including a single layer of the first example A1 is formed of a K-rich piezoelectric body where the K ratio is higher than the Na ratio. In the piezoelectric body including a single layer of the second example A2, K is 35 [mol %], and Na is 65 [mol %]. That is, the piezoelectric body including a single layer of the second example A2 is formed of a Na-rich piezoelectric body where the Na ratio is higher than the K ratio.

As can be seen from a comparison between the first example A1 and the second example A2, the positive saturated polarization +Pm1 of the first example A1 is higher than the positive saturated polarization +Pm2 of the second example A2. Accordingly, it can be seen that, in the K-rich piezoelectric body, the positive saturated polarization +Pm can be increased as compared to the Na-rich piezoelectric body.

The third example A3 is a piezoelectric layer 53x including a lower piezoelectric body and an upper piezoelectric body. In each of the lower piezoelectric body and the upper piezoelectric body in the third example A3, K is 65 [mol %], and Na is 35 [mol %]. Accordingly, the piezoelectric layer 53x of the third example A3 is formed of a laminate including two K-rich piezoelectric bodies. In the lower piezoelectric body and the upper piezoelectric body of the third example A3, the K contents are the same as each other.

The fourth example A4 is the piezoelectric layer 53 including the lower piezoelectric body 531 and the upper piezoelectric body 532. In the upper piezoelectric body 532 of the fourth example A4, K is 35 [mol %], and Na is 65 [mol %]. In the lower piezoelectric body 531 of the fourth example A4, K is 65 [mol %], and Na is 35 [mol %]. Accordingly, in the piezoelectric layer 53 of the fourth example A4, the K content in the lower piezoelectric body 531 is higher than the K content in the upper piezoelectric body 532. In addition, in the fourth example A4, the upper piezoelectric body 532 is formed of a Na-rich piezoelectric body, and the lower piezoelectric body 531 is formed of a K-rich piezoelectric body.

The positive saturated polarization +Pm3 of the third example A3 and the positive saturated polarization +Pm4 of the fourth example A4 are higher than the positive saturated polarization +Pm1 of the first example A1 and the positive saturated polarization +Pm2 of the second example A2. Therefore, according to the laminate including the KNN piezoelectric bodies, the positive saturated polarization +Pm can be increased to be higher than that of the single layer of the KNN piezoelectric body. In particular, in the third example A3, the positive saturated polarization +Pm is the highest among the four examples. That is, with the laminate including the plural layers of the K-rich piezoelectric bodies, the positive saturated polarization +Pm can be particularly increased. On the other hand, the positive saturated polarization +Pm4 of the fourth example A4 is higher than the positive saturated polarization +Pm1 of the first example A11 and the positive saturated polarization +Pm2 of the second example A2, but is lower than the positive saturated polarization +Pm3 of the third example A3.

In addition, the positive saturated polarization +Pm of the fourth example A4 is lower than that of the third example A3 and is higher than that of the first example A1. That is, in the laminate including the upper layer and the lower layer where the K content is higher than that in the upper layer, the positive saturated polarization +Pm is lower than that in the laminate including the plural K-rich layers, but the positive saturated polarization +Pm can be increased to be higher than that in the single K-rich layer.

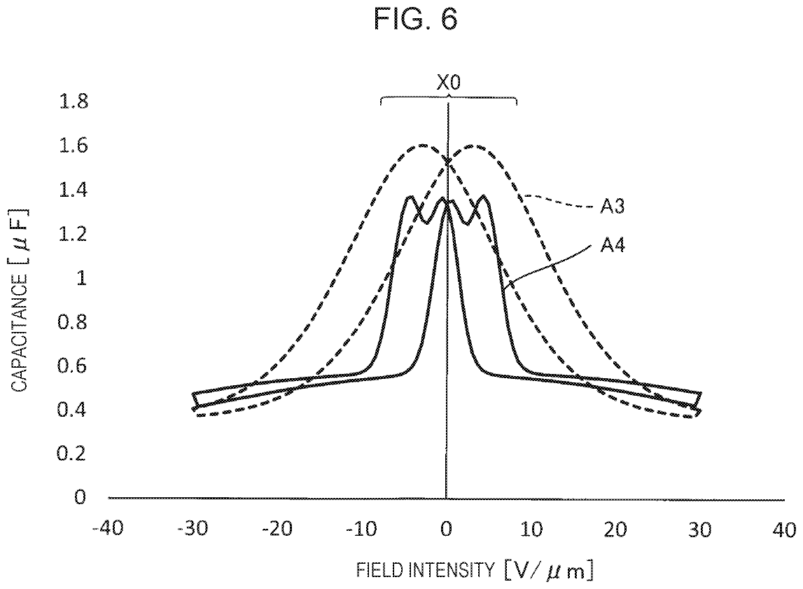

FIG. 6 is a diagram illustrating a relationship between a field intensity and a capacitance regarding the third example A3 and the fourth example A4 of FIG. 5. In FIG. 6, the horizontal axis represents a field intensity [V/μm], and the vertical axis represents a capacitance [μF].

As illustrated in FIG. 6, in the third example A3, the capacitance is locally increased in a region X0. As in the third example A3, when both of the saturated polarizations +Pm of the lower piezoelectric body 531 and the upper piezoelectric body 532 are increased, the capacitance is locally increased. Therefore, high-frequency driving is interrupted, and a delay may occur in the driving.

On the other hand, in the fourth example A4, a local increase in capacitance is not found in the region X0 unlike the third example A3. That is, by increasing the K content in the upper piezoelectric body 532 to be higher than the K content in the lower piezoelectric body 531 as in the fourth example A4, a concern where a driving delay may occur can be suppressed as compared to the laminate including the plural K-rich layers as in the third example A3.

As can be seen from FIGS. 5 and 6, by increasing the K content in the lower piezoelectric body 531 to be higher than the K content in the upper piezoelectric body 532, the occurrence of a driving delay can be suppressed as compared to the laminate including the plural K-rich layers. That is, the average concentrations K1, K2, Na1, and Na2 satisfy the relationship of K1/(K1+Na1)>K2/(K2+Na2), the occurrence of the driving delay in the high-frequency driving can be suppressed.

In addition, it is preferable that the upper piezoelectric body 532 is an Na-rich layer and the lower piezoelectric body 531 is a K-rich layer as in the fourth example A4. That is, it is preferable that the average concentrations K1, K2, Na1, and Na2 satisfy a relationship of K1/(K1+Na1)>0.50>K2/(K2+Na2). When the average concentrations K1, K2, Na1, and Na2 satisfy the above-described relationship, the occurrence of cracking caused by sudden application of an overcurrent and the occurrence of a driving delay can be effectively suppressed simultaneously, as compared to when the average concentrations K1, K2, Na1, and Na2 does not satisfy the above-described relationship.

When the average concentrations K1, K2, Na1, and Na2 satisfy the relationship of K1/(K1+Na1)>0.50>K2/(K2+Na2), the lower piezoelectric body 531 does not need to be a K-rich layer. Likewise, the upper piezoelectric body 532 does not need to be an Na-rich layer.

It is preferable that the average concentrations K1, K2, Na1, and Na2 satisfy 0.20≤K1/(K1+Na1)−K2/(K2+Na2)≤0.40. In addition, it is preferable that the average concentrations K1 and Na1 in the lower piezoelectric body 531 satisfy a relationship of K1/(K1+Na1)≥0.60. In addition, it is preferable that the average concentrations K1 and Na1 in the lower piezoelectric body 531 satisfy K1/(K1+Na1)≤0.70. In addition, it is preferable that the average concentrations K2 and Na2 in the upper piezoelectric body 532 satisfy K2/(K2+Na2)≤0.40. In addition, it is preferable that the average concentrations K2 and Na2 in the upper piezoelectric body 532 satisfy K2/(K2+Na2)≥0.30. The reasons for these configurations will be described below.

In addition, as described above, when the average concentrations K1, K2, Na1, and Na2 satisfy the relationship of K1/(K1+Na1)>K2/(K2+Na2), the saturated polarization Pm of the lower piezoelectric body 531 can be increased to be higher than the saturated polarization Pm of the upper piezoelectric body 532. That is, the saturated polarization Pm of the upper piezoelectric body 532 can be reduced to be lower than the saturated polarization Pm of the lower piezoelectric body 531. Therefore, the occurrence of cracking caused by sudden application of an overcurrent and the occurrence of a driving delay can be effectively suppressed simultaneously.

For example, it is preferable that the positive saturated polarization +Pm in the upper piezoelectric body 532 is 15.5 [μC/cm²] or lower. When the positive saturated polarization +Pm in the lower piezoelectric body 531 is the above-described value or lower, the occurrence of a driving delay of the piezoelectric element 5 can be effectively reduced as compared to when the positive saturated polarization +Pm in the lower piezoelectric body 531 exceeds the above-described value.

For example, it is preferable that the positive saturated polarization +Pm in the lower piezoelectric body 531 is 19.5 [μC/cm²] or higher. When the positive saturated polarization +Pm in the lower piezoelectric body 531 is the above-described value or higher, the piezoelectric constant of the lower piezoelectric body 531 can be increased as compared to when the positive saturated polarization +Pm in the lower piezoelectric body 531 is lower than the above-described value. Accordingly, the displacement of the piezoelectric layer 53 in the high voltage range can be decreased, and thus a concern of cracking caused by sudden application of an unexpected overcurrent to the piezoelectric layer 53 can be effectively suppressed.

The positive saturated polarization +Pm in the upper piezoelectric body 532 may exceed 15.5 [μC/cm²]. In addition, the positive saturated polarization +Pm in the lower piezoelectric body 531 may be lower than 19.5 [μC/cm²].

In addition, when an average concentration of Nb in the lower piezoelectric body 531 is represented by Nb1 and an average concentration of Nb in the upper piezoelectric body 532 is represented by Nb2, it is preferable that the average concentrations K1, K2, Na1, Na2, Nb1, and Nb2 satisfy the following relationship.

$$0. 9 < \{ Nb 2 / ( K 2 + Na 2 + Nb 2 ) \} / Nb 1 / ( K 1 + Na 1 + Nb 1 ) \} < 1.1$$

The average concentrations K1, K2, Na1, Na2, Nb1, and Nb2 satisfying the following relationship represents that Nb in the B-site has substantially no difference between the lower piezoelectric body 531 and the upper piezoelectric body 532. When a difference between Nb of the lower piezoelectric body 531 and Nb of the upper piezoelectric body 532 excessively increases, peeling between the lower piezoelectric body 531 and the upper piezoelectric body 532 may occur.

In addition, it is preferable that the thickness of the upper piezoelectric body 532 is more than the thickness of the lower piezoelectric body 531. Each of the thicknesses is a length along the Z2 direction that is the lamination direction. The upper piezoelectric body 532 largely relates to the displacement characteristics of the piezoelectric element 5. Therefore, when the thickness of the upper piezoelectric body 532 is more than the thickness of the lower piezoelectric body 531, the displacement characteristics of the piezoelectric element 5 can be improved as compared to when the thickness of the upper piezoelectric body 532 is less than the thickness of the lower piezoelectric body 531.

The thickness of the upper piezoelectric body 532 may be the thickness of the lower piezoelectric body 531 or less.

Hereinafter, an example of the piezoelectric layer 53 will be described with reference to Examples and Comparative Examples.

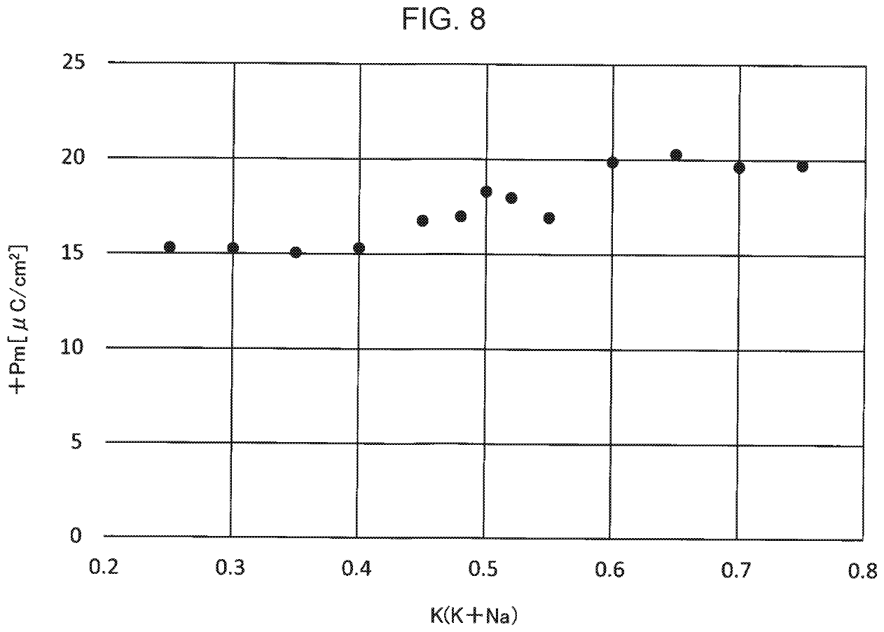

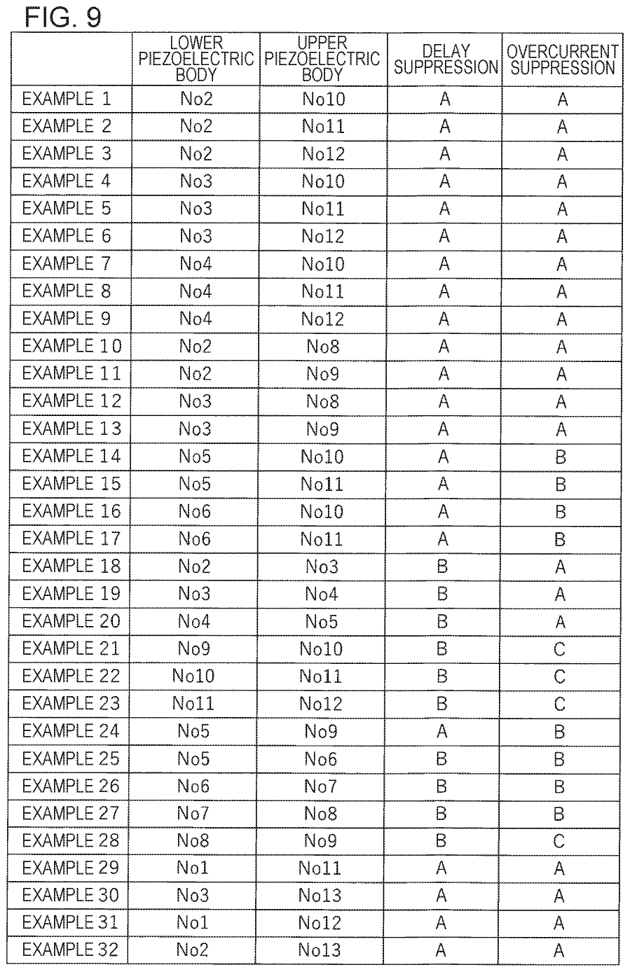

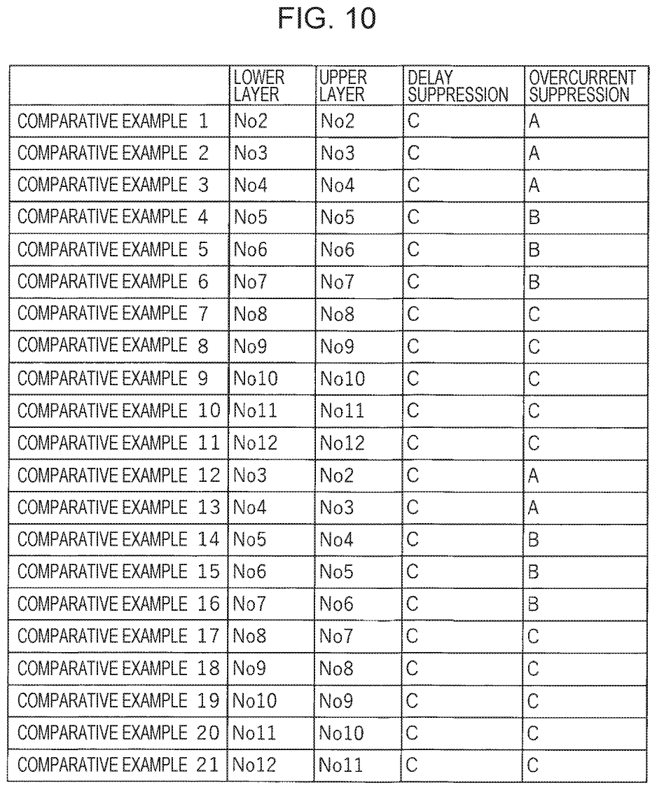

FIG. 7 is a table illustrating a relationship between the K content and the positive saturated polarization +Pm. FIG. 8 is a graph illustrating the relationship between the K content and the positive saturated polarization +Pm. FIG. 9 is a table illustrating Examples. FIG. 10 is a table illustrating Comparative Examples. For the lower piezoelectric body and the upper piezoelectric body in Examples of FIG. 9 and Comparative Examples of FIGS. 10, 13 types of KNN piezoelectric bodies of No. 1 to No. 13 illustrated in FIG. 7 are used.

In FIG. 7, regarding the 13 types of KNN piezoelectric bodies of No. 1 to No. 13, the average concentrations of K, Na, and Nb, K/(K+Na), and the positive saturated polarization +Pm are illustrated. The 13 types of KNN piezoelectric bodies of No. 1 to No. 13 are formed of a single layer. The 13 types of KNN piezoelectric bodies of No. 1 to No. 13 are formed of a single layer, but even when the KNN piezoelectric bodies are formed of plural layers having the same composition with the same manufacturing method, substantially the same tendency as the values shown in FIG. 7 is shown.

In No. 1 to No. 6, the average concentration of K is higher than the average concentration of Na. Among No. 1 to No. 6, the average concentration of K is the highest in No. 1, and the average concentration of K decreases in order of No. 1 to No. 6. In No. 7, the average concentration of K and the average concentration of Na are the same as each other. In No. 8 to No. 13, the average concentration of K is lower than the average concentration of Na. Among No. 8 to No. 13, the average concentration of K is the lowest in No. 13, and the average concentration of K increases in order of No. 8 to No. 13.

In FIG. 8, the relationship between the K content and the positive saturated polarization +Pm in No. 1 to No. 13 of FIG. 7 is illustrated. In FIG. 8, the horizontal axis represents K/(K+Na), and the vertical axis represents the positive saturated polarization +Pm. For example, a plot on the rightmost side of FIG. 8 is No. 1. A plot on the leftmost side of FIG. 8 is No. 13.

As illustrated in FIGS. 7 and 8, in No. 1 to No. 6, the positive saturated polarization +Pm is higher than that of No. 8 to No. 13. By increasing the K content, the positive saturated polarization +Pm can be increased. Therefore, the piezoelectric constant can be increased, and the displacement characteristics can be improved.

As illustrated in FIGS. 9 and 10, in the piezoelectric layers according to Examples and Comparative Examples, the KNN piezoelectric body of any one of No. 1 to No. 13 of FIG. 7 was used for each of the upper piezoelectric body and the lower piezoelectric body.

For example, in Example 1, No. 2 was used for the lower piezoelectric body, and No. 10 was used for the upper piezoelectric body. That is, in the lower piezoelectric body according to Example 1, the average concentration K1 is 70 [mol %], and the average concentration Na1 is 30 [mol %]. In the upper piezoelectric body according to Example 1, the average concentration K2 is 40 [mol %], and the average concentration Na1 is 60 [mol %]. Accordingly, in Example 1, the K content in the lower piezoelectric body is higher than the K content in the upper piezoelectric body.

As in Example 1, in each of Examples 2 to 30, the K content in the lower piezoelectric body is higher than the K content in the upper piezoelectric body. That is, in each of Examples 1 to 30, K1/(K1+Na1)>K2/(K2+Na2) is satisfied. On the other hand, in each of Comparative Examples 1 to 30, the K content in the upper piezoelectric body is lower than or equal to the K content in the lower piezoelectric body. That is, in each of Comparative Examples 1 to 21, K1/(K1+Na1)>K2/(K2+Na2) is not satisfied.

In Examples 1 to 32, the saturated polarization Pm of the upper piezoelectric body is lower than the saturated polarization Pm of the lower piezoelectric body. According to each of Examples, the occurrence of cracking caused by sudden application of an overcurrent and the occurrence of a driving delay can be effectively suppressed simultaneously.

In Examples and Comparative Examples, the lower electrodes have the same configuration. Likewise, in Examples and Comparative Examples, the upper electrodes have the same configuration. In addition, in Examples and Comparative Examples, the thicknesses of the upper piezoelectric bodies are the same. In Examples and Comparative Examples, the thicknesses of the lower piezoelectric bodies are the same.

In FIGS. 8 and 9, evaluation results regarding the delay suppression and evaluation results regarding the displacement are illustrated.

### Evaluation Method of Driving Delay

The evaluation regarding the driving delay suppression was performed based on unevenness of an image when the piezoelectric element was driven at a predetermined driving frequency. In this evaluation, for example, the predetermined driving frequency was 60 kHz. The evaluation was performed based on the following grades A, B, and C.
A: unevenness was not substantially found in an image that was formed by performing scanning once during driving at a frequency of 60 kHz.
B: unevenness was slightly found in a scanning direction in an image that was formed by performing scanning once during driving at a frequency of 60 kHz.
C: unevenness was frequently found in the scanning direction in an image that was formed by performing scanning once during driving at a frequency of 60 kHz.

When the driving is delayed, an ejection timing is delayed. As a result, dots formed at a medium deviate from ideal landing positions to positions on the downstream side in the scanning direction. When it is originally desired to land all the dots at regular intervals in the scanning direction, the occurrence of the above-described deviation in landing position is recognized as unevenness of an image.

### Evaluation Method of Overcurrent

By continuously performing the ejecting operation until an ideal duration number of shots, the evaluation of an overcurrent was performed based on the degree of damage of the piezoelectric element. The ideal duration number of shots is the number of ink droplets ejected per nozzle that can compensate for the original performance. In this evaluation, the ideal duration number of shots is, for example, one hundred billion shots.
A: substantially no damage of the piezoelectric element was found until the ideal duration number of shots.
B: the damage of the piezoelectric element was found when about 80% to 90% of the ideal duration number of shots was reached.
C: the damage of the piezoelectric element was found when about 80% or less of the ideal duration number of shots was reached.

As the number of shots increases, damage to the piezoelectric layer by the overcurrent cumulatively increases. As a result, the durability of the piezoelectric layer decreases, and thus the damage to the piezoelectric element occurs.

As can be seen from FIGS. 9 and 10, when Examples 1 to 32 and Comparative Examples 1 to 21 are compared to each other, it can be seen that Examples 1 to 32 are excellent in the evaluation regarding the delay suppression and the evaluation regarding the overcurrent suppression. Here, by satisfying K1/(K1+Na1)>K2/(K2+Na2), the occurrence of an overcurrent can be suppressed and the occurrence of a driving delay in the high-frequency driving can be reduced simultaneously.

In particular, in Examples 1 to 17, 24, 29, and 30, the lower piezoelectric body is a K-rich layer, and the upper piezoelectric body is an Na-rich layer. That is, in Examples 1 to 17, 24, 29, and 30, the average concentrations K1, K2, Na1, and Na2 satisfy the following relationship of (Expression 1).

$$K 1 / ( K 1 + Na 1 ) > 0.5 > K 2 / ( K 2 + Na 2 ) \qquad ( Expression 1 )$$

In Examples 1 to 17, 24, and 29 to 32, the evaluation regarding the delay characteristics was A, and unevenness does not occur in the image.

In addition, in Examples 1 to 17, 24, 29, and 30, the evaluation regarding the suppression of the overcurrent was A or B, and damage to the piezoelectric element was not found until the ideal duration number of shots, or, even when the damage was found, the damage occurred after 80% of the ideal duration number of shots was reached. This way, in Examples 1 to 17, 24, and 29 to 32, the occurrence of a driving delay was suppressed, and the occurrence of cracking caused by sudden application of an overcurrent can be suppressed in an allowable range.

Further, in the upper piezoelectric body and the lower piezoelectric body, it is preferable that a difference in the K content in the A-site, that is, K1/(K1+Na1) K2/(K2+Na2) is not excessively large. The reason for this is as follows. When this difference is excessively large, there is a large difference in the saturated polarization Pm between the upper piezoelectric body and the lower piezoelectric body. As a result, a difference in the degree of strain increases, and thus there is a deviation between the upper piezoelectric body and the lower piezoelectric body. Specifically, it is preferable to satisfy the following (Expression 2).

$$( K 1 / ( K 1 + N a1 ) - K 2 / ( K 2 + Na 2 ) \leq 0.4 \qquad ( Expression 2 )$$

On the other hand, it is also not preferable that the difference in the K content in the A-site is not excessively small. The difference being small represents that the composition ratio of the A-site does not significantly change between the upper piezoelectric body and the lower piezoelectric body. The upper piezoelectric body and the lower piezoelectric body are member to be laminated, and the composition of the A-site is common, which includes K and Na. Therefore, for example, even when the magnitude relationship of the composition varies, a phenomenon in which the elements move between the piezoelectric bodies over time such that the composition ratio is flat occurs. When the difference in the K content in the A-site is excessively small, a driving delay or the occurrence of cracking can be suppressed at first; however, the effect of the element movement cannot be sufficiently canceled, and there is a problem in that a problem may occur after use for a long period of time. Specifically, it is preferable to satisfy the following (Expression 3).

$$0.2 \leq K 1 / ( K 1 + Na 1 ) K 2 / ( K 2 + Na 2 ) \qquad ( Expression 3 )$$

In summary, it is preferable that the difference in the K content in the A-site is not excessively large and is not excessively small, that is, (Expression 4) obtained by integrating (Expression 2) and (Expression 3) is satisfied.

$$0.2 \leq K 1 / ( K 1 + Na 1 ) - K 2 / ( K 2 + Na 2 ) \leq 0.4 \qquad ( Expression 4 )$$

In Examples 1 to 11, 13, 15, 29, and 30, (Expression 4) is satisfied. In these examples, the deviation between the piezoelectric layers or the occurrence of the problem after use for a long period of time did not occur. On the other hand, for example, in Examples 31 and 32, K1/(K1+Na1)−K2/(K2+Na2)>0.40 is satisfied, and thus there was a deviation between the upper piezoelectric body and the lower piezoelectric body. In addition, for example, in Examples 12, 14, and 16 to 28, K1/(K1+Na1) K2/(K2+Na2)<0.20 is satisfied, and thus a driving delay or a displacement deterioration after use for a long period of time may occur.

Here, in order to satisfy both of (Expression 1) and (Expression 3), it can be seen that K1/(K1+Na1) and K2/(K2+Na2) are within a range of ±0.10 from 0.50 as a boundary. Specifically, it is preferable that (Expression 5) and (Expression 6) are satisfied.

$$K 1 / ( K 1 + Na 1 ) \geq 0.6 \qquad ( Expression 5 )$$

$$K 2 / ( K 2 + N a 2 ) \leq 0.4 \qquad ( Expression 6 )$$

In Examples 1 to 13, 18 to 20, and 29 to 32, (Expression 5) is satisfied. In addition, in Examples 1 to 9, 14 to 17, 21 to 23, and 29 to 32, (Expression 6) is satisfied.

Here, in order to satisfy both of (Expression 1) and (Expression 2), it can be seen that K1/(K1+Na1) and K2/(K2+Na2) may be within a range of ±0.20 from 0.50 as a boundary. Specifically, it is preferable that not only (Expression 5) but also (Expression 7) and not only (Expression 6) but also (Expression 8) are satisfied.

$$K 1 / ( K 1 + N a 1 ) \leq 0.7 \qquad ( Expression 7 )$$

$$K2 / ( K 2 + N a 2 ) \geq 0.3 \qquad ( Expression 8 )$$

In Examples 1 to 13, 18 to 20, and 30 to 32, (Expression 5) and (Expression 7) are satisfied. In addition, in Examples 1 to 9, 14 to 17, 21 to 23, and 29, 31, and 32, (Expression 6) and (Expression 8) are satisfied.

As described above, in the present disclosure, K1/(K1+Na1)>K2/(K2+Na2) needs to be satisfied. When (Expression 1) to (Expression 8) are integrated, it can be seen that it is more preferable to satisfy 0.60≤K1/(K1+Na1)≤0.70 and 0.30≤K2/(K2+Na2)≤0.40. In Examples 1 to 9, the expressions are satisfied.

As described above, when the value of Nb in the B-site largely varies between the upper piezoelectric body and the lower piezoelectric body, there is a problem in that a deviation occurs between the piezoelectric bodies. Therefore, in Examples 1 to 32, the value of Nb is substantially the same between the upper piezoelectric body and the lower piezoelectric body. Specifically, 0.90<{Nb2/(K2+Na2+Nb2)}/{Nb1/(K1+Na1+Nb1)}<1.10.

### 2. Modified Examples

The embodiments described above may be modified in various ways. A specific modification aspect that can be applied to the embodiments described above will be described below. Two or more aspects optionally selected from the following examples can be combined as appropriate within a range in which the aspects are not mutually contradictory.

The “liquid ejecting head” may be a circulation type head having a so-called circulation flow path.

The “image forming device” may be adopted in various devices such as facsimile devices and copy machines, in addition to devices dedicated to printing. The use of the image forming device is not limited to printing. For example, image forming devices that eject a coloring material solution are used as manufacturing devices that form a color filter for display devices such as liquid crystal display panels. In addition, image forming devices that eject a solution of a conductive material are used as manufacturing devices that form wiring and electrodes of a wiring substrate. In addition, image forming devices that eject a solution of an organic substance related to a living body are used, for example, as manufacturing devices for manufacturing biochips.

The piezoelectric element according to the present disclosure is not limited to the liquid ejecting head or the liquid ejecting apparatus, and may be a device having a function of converting a voltage and a mechanical force to each other, for example, applying a voltage to generate a mechanical force or applying a mechanical force to generate a voltage. The piezoelectric element according to the present disclosure may be, for example, an ultrasonic motor, a vibration type dust removing device, a piezoelectric transformer, a piezoelectric speaker, a piezoelectric pump, an ultrasonic wave detector, an angular velocity sensor, an acceleration sensor, a vibration sensor, an inclination sensor, a pressure sensor, a collision sensor, a human sensor, an infrared sensor, a terahertz sensor, a heat detection sensor, a pyroelectric sensor, a piezoelectric sensor, a ferroelectric memory (FeRAM), a ferroelectric transistor (FeFET), a ferroelectric logic (FeLogic), a ferroelectric capacitor, a wavelength converter, an optical waveguide, an optical path modulator, a refractive index control element, or an electronic shutter mechanism.

The present disclosure is described above based on the preferred embodiments, but the present disclosure is not limited to the above embodiments. In addition, the configuration of each portion of the present disclosure can be replaced with any configuration having the same function in the above-described embodiments, and any configuration can be added.

What is claimed is:

1. A piezoelectric element comprising:
a lower electrode;
a lower piezoelectric body including K, Na, and Nb;
an upper piezoelectric body including K, Na, and Nb; and
an upper electrode, wherein
the lower electrode, the lower piezoelectric body, the upper piezoelectric body, and the upper electrode are provided to be arranged in this order in a lamination direction, and
when an average concentration of K in the lower piezoelectric body is represented by K1,
an average concentration of Na in the lower piezoelectric body is represented by Na1,
an average concentration of K in the upper piezoelectric body is represented by K2, and
an average concentration of Na in the upper piezoelectric body is represented by Na2, K1/(K1+Na1)>K2/(K2+Na2) is satisfied.

2. The piezoelectric element according to claim 1, wherein K1/(K1+Na1)>0.50>K2/(K2+Na2) is satisfied.

3. The piezoelectric element according to claim 1, wherein 0.20≤K1/(K1+Na1)−K2/(K2+Na2)≤0.40 is satisfied.

4. The piezoelectric element according to claim 1, wherein K1/(K1+Na1)≥0.60 is satisfied.

5. The piezoelectric element according to claim 3, wherein K1/(K1+Na1)≤0.70 is satisfied.

6. The piezoelectric element according to claim 1, wherein K2/(K2+Na2)≤0.40 is satisfied.

7. The piezoelectric element according to claim 5, wherein K2/(K2+Na2)≥0.30 is satisfied.

8. The piezoelectric element according to claim 1, wherein
when an average concentration of Nb in the lower piezoelectric body is represented by Nb1, and
an average concentration of Nb in the upper piezoelectric body is represented by Nb2,
0.90<{Nb2/(K2+Na2+Nb2)}/{Nb1/(K1+Na1+Nb1)}<1.10 is satisfied.

9. The piezoelectric element according to claim 1, wherein a saturated polarization in the lower piezoelectric body is larger than a saturated polarization in the upper piezoelectric body.

10. The piezoelectric element according to claim 9, wherein the saturated polarization in the upper piezoelectric body is 15.5 [μC/cm²] or lower.

11. The piezoelectric element according to claim 9, wherein the saturated polarization in the lower piezoelectric body is 19.5 [μC/cm²] or higher.

12. The piezoelectric element according to claim 1, wherein the upper piezoelectric body is thicker than the lower piezoelectric body.

13. A liquid ejecting head comprising:
the piezoelectric element according to claim 1;
a pressure chamber in which liquid is circulated to apply a pressure to the liquid by the piezoelectric element; and
a nozzle configured to eject the liquid using the pressure applied in the pressure chamber.

14. A liquid ejecting apparatus comprising:
a liquid ejecting head according to claim 13; and
a controller configured to control an ejecting operation from the liquid ejecting head.
